(19) United States
(12) Patent Application Publication
(10) Pub. No.: US 2026/0077363 A1
(43) Pub. Date: Mar. 19, 2026

(54) CHEMICAL LIQUID PURIFICATION APPARATUS FOR SEMICONDUCTOR MANUFACTURING AND CHEMICAL LIQUID TRANSFERRING SYSTEM FOR SEMICONDUCTOR MANUFACTURING

(71) Applicant: SAMSUNG ELECTRONICS CO., LTD., Suwon-si (KR)

(72) Inventors: Ji Hyun KIM, Seoul-si (KR); Yun Ho KIM, Suwon-si (KR); Jin Hyeok JANG, Suwon-si (KR); Young Hun KIM, Suwon-si (KR); Jun Young OH, Suwon-si (KR); Dong Gyu LEE, Seoul-si (KR); Seungyun LEE, Seoul-si (KR); Hyo Ri LEE, Suwon-si (KR); Sam Jong CHOI, Suwon-si (KR)

(73) Assignees: SAMSUNG ELECTRONICS CO., LTD., Suwon-si (KR); Seoul National University R&DB FOUNDATION, Seoul (KR)

(21) Appl. No.: 19/187,436

(22) Filed: Apr. 23, 2025

(30) Foreign Application Priority Data
Sep. 13, 2024 (KR) 10-2024-0125820
Nov. 6, 2024 (KR) 10-2024-0156428

(51) Int. Cl. B03C 5/02; B01D 21/26; B01D 36/04; B03C 5/00; H01L 21/67

(52) U.S. Cl. CPC B03C 5/026; B01D 21/262; B01D 36/045; B03C 5/005; H10P 72/0402

(57) ABSTRACT

A chemical liquid purification apparatus for semiconductor manufacturing includes a first tank configured to store a chemical liquid for semiconductor manufacturing containing impurities; a first line configured to supply the chemical liquid for semiconductor manufacturing to the first tank; a first electrode and a second electrode provided inside the first tank; a DC power supply connected to each of the first electrode and the second electrode; a second line configured to supply the chemical liquid for semiconductor manufacturing processed in the first tank to outside of the first tank; and a first centrifuge which selectively separates the impurities inside the chemical liquid for semiconductor manufacturing moving along the second line.

### CROSS-REFERENCE TO RELATED APPLICATIONS

This application claims priority from Korean Patent Application No. 10-2024-0125820 filed on Sep. 13, 2024 and No. 10-2024-0156428 filed on Nov. 6, 2024 in the Korean Intellectual Property Office, and all the benefits accruing therefrom under 35 U.S.C. 119, the contents of which in their entirety are herein incorporated by reference.

### BACKGROUND

### 1. Field

The present disclosure relates to a chemical liquid purification apparatus for semiconductor manufacturing and a chemical liquid transferring system for semiconductor manufacturing.

### 2. Description of Related Art

As semiconductor processes are miniaturized, impurities such as particles and metal ions of extremely small sizes become the cause of defects. Removal of such impurities from various chemical liquids used in a semiconductor process acts as an important factor for enhancing yield of a wafer. Therefore, research on technologies for purifying impurities contained in the chemical liquid for semiconductor manufacturing and recovering high-purity chemical liquid is being conducted.

### SUMMARY

Aspects of the present disclosure provide a chemical liquid purification apparatus for semiconductor manufacturing with improved impurity purification effects.

Aspects of the present disclosure also provide a chemical liquid transferring system for semiconductor manufacturing with improved impurity purification effects.

However, aspects of the present disclosure are not restricted to those set forth herein. The above and other aspects of the present disclosure will become more apparent to one of ordinary skill in the art to which the present disclosure pertains by referencing the detailed description given below.

According to an aspect of the present disclosure, there is provided a chemical liquid purification apparatus for semiconductor manufacturing comprising a first tank configured to store a chemical liquid for semiconductor manufacturing containing impurities; a first line configured to supply the chemical liquid for semiconductor manufacturing to the first tank; a first electrode and a second electrode provided inside the first tank; a DC power supply connected to each of the first electrode and the second electrode; a second line configured to supply the chemical liquid for semiconductor manufacturing processed in the first tank to outside of the first tank; and a first centrifuge which selectively separates the impurities inside the chemical liquid for semiconductor manufacturing moving along the second line.

According to the aforementioned and other embodiments of the present disclosure, a chemical liquid purification apparatus for semiconductor manufacturing comprises a first tank configured to store a chemical liquid for semiconductor manufacturing containing impurities; a first line configured to supply the chemical liquid for semiconductor manufacturing to the first tank; a first electrode and a second electrode provided inside the first tank; a DC power supply configured to supply a DC current to each of the first electrode and the second electrode; a second line configured to supply the chemical liquid for semiconductor manufacturing processed in the first tank to the outside of the first tank; a centrifuge which selectively separates impurities in the chemical liquid for semiconductor manufacturing moving along the second line and stores the impurities in a first region and a second region separated from each other; a third line configured to supply the chemical liquid for semiconductor manufacturing separated into the first region to the outside of the centrifuge; a filter configured to filter impurities in the chemical liquid for semiconductor manufacturing moving along the third line; and a second tank connected to the filter through the third line, wherein a particle size of the impurities in the chemical liquid for semiconductor manufacturing separated into the first region is smaller than a particle size of the impurities in the chemical liquid for semiconductor manufacturing separated into the second region.

According to the aforementioned and other embodiments of the present disclosure, a chemical liquid transferring system for semiconductor manufacturing comprises a manufacturing assembly configured to manufacture a chemical liquid for semiconductor manufacturing containing impurities; a supplying assembly configured to supply the chemical liquid for semiconductor manufacturing manufactured in the manufacturing assembly to an outside; and a processing assembly configured to receive the chemical liquid for semiconductor manufacturing from the supplying assembly and process a wafer, using the received chemical liquid for semiconductor manufacturing, wherein at least one of the manufacturing assembly, the supplying assembly, and the processing assembly includes a chemical liquid purification apparatus for semiconductor manufacturing, wherein the chemical liquid purification apparatus for semiconductor manufacturing includes a first tank configured to store the chemical liquid for semiconductor manufacturing; a first line configured to supply the chemical liquid for semiconductor manufacturing to the first tank; a first electrode and a second electrode provided inside the first tank; a DC power supply configured to supply a DC current to each of the first electrode and the second electrode; a second line configured to supply the chemical liquid for semiconductor manufacturing processed in the first tank to the outside of the first tank; and a first centrifuge which selectively separates impurities in the chemical liquid for semiconductor manufacturing moving along the second line.

### BRIEF DESCRIPTION OF DRAWINGS

The above and other aspects and features of the present disclosure will become more apparent by describing in detail exemplary embodiments thereof with reference to the accompanying drawings, in which:

FIG. 1 is a schematic diagram showing a chemical liquid transferring system for semiconductor manufacturing according to some embodiments.

FIG. 2 is a schematic diagram that schematically shows the chemical liquid purification apparatus for semiconductor manufacturing according to some embodiments.

FIG. 3 is a flowchart for explaining a method for purifying a chemical liquid for semiconductor manufacturing according to some embodiments.

FIGS. 4 to 7 are diagrams for explaining impurity flocculation in the chemical liquid for semiconductor manufacturing according to some embodiments.

FIG. 8 is a schematic diagram that schematically shows a chemical liquid transferring system for semiconductor manufacturing according to some embodiments.

FIG. 9 is a schematic diagram showing a chemical liquid purification apparatus for semiconductor manufacturing according to some embodiments.

FIGS. 10 to 12 are graphs for explaining the flocculation of impurities in the chemical liquid for manufacturing semiconductor according to some embodiments.

FIGS. 13 and 14 are graphs for explaining selective centrifugation of impurities inside the chemical liquid for manufacturing semiconductor according to some embodiments.

FIG. 15 is a schematic diagram that schematically shows a chemical liquid transferring system for semiconductor manufacturing according to some embodiments.

FIGS. 16 and 17 are schematic diagrams that schematically show a chemical liquid purification apparatus for semiconductor manufacturing inside the piping line of FIG. 15.

FIG. 18 is a schematic diagram showing a chemical liquid transferring system for semiconductor manufacturing according to some embodiments.

FIG. 19 is a schematic diagram that schematically shows the chemical liquid transferring system for semiconductor manufacturing according to some embodiments.

### DETAILED DESCRIPTION

Hereinafter, a chemical liquid purification apparatus for semiconductor manufacturing and a chemical liquid transferring system for semiconductor manufacturing according to some embodiments will be described referring to the accompanying drawings. The same reference numerals are given to the same elements in the drawings, and repeated descriptions thereof are omitted.

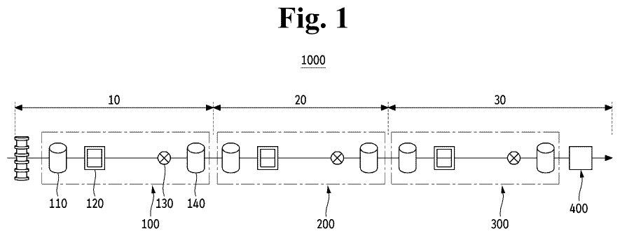

FIG. 1 is a schematic diagram showing a chemical liquid transferring system for semiconductor manufacturing according to some embodiments.

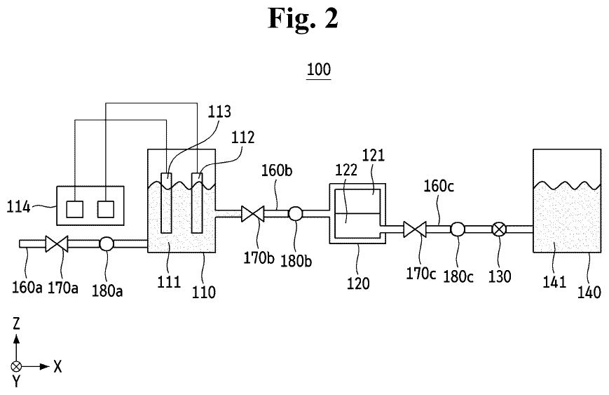

Referring to FIG. 1, a chemical liquid transferring system 1000 for semiconductor manufacturing may include a manufacturing assembly 10, a supplying assembly 20, and a processing assembly 30. The manufacturing assembly 10 may be configured to manufacture a chemical liquid 111 for semiconductor manufacturing, which will be described below referring to FIG. 2. The chemical liquid 111 for semiconductor manufacturing may include a chemical liquid used in a semiconductor process. For example, the chemical liquid 111 for semiconductor manufacturing is a chemical liquid used in a cleaning process, an exposure process, an etching process, a development process, a deposition process, and the like, and may include ultra-pure water (UPW), a liquefied or gaseous organic compound, a non-ionic liquid, or the like. Further, the chemical liquid 111 for semiconductor manufacturing may be a liquid containing at least one of hydrogen peroxide, sulfuric acid, phosphoric acid, hydrochloric acid, ammonium hydroxide, isopropyl alcohol (IPA), thinner, tetramethylammonium hydroxide (TMAH), developer, and hydrofluoric acid.

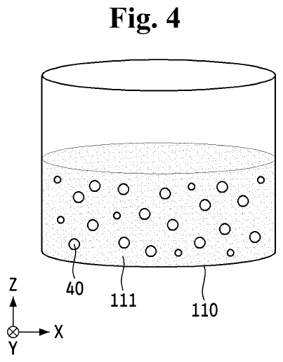

In some embodiments, the chemical liquid 111 for semiconductor manufacturing may contain a photoresist of a liquid form. However, the chemical liquid 111 for semiconductor manufacturing is a chemical liquid used in the semiconductor manufacturing process, and a chemical liquid containing impurities is sufficient. The impurities contained in the chemical liquid 111 for semiconductor manufacturing will be described below referring to FIG. 4 or the like.

The supplying assembly 20 may be configured to provide the chemical liquid 111 for semiconductor manufacturing manufactured in the manufacturing assembly 10 to the processing assembly 30. For example, the supplying assembly 20 may be a place in which the chemical liquid 111 for semiconductor manufacturing manufactured in the manufacturing assembly 10 is temporarily stored before being provided to the processing assembly 30. Also, the supplying assembly 20 may perform an additional process on the chemical liquid 111 for semiconductor manufacturing manufactured in the manufacturing assembly 10. The additional process may refer to a chemical or physical process newly applied to the chemical liquid 111 for semiconductor manufacturing.

The processing assembly 30 may be configured to process a wafer, using the chemical liquid 111 for semiconductor manufacturing provided from the supplying assembly 20. For example, the processing assembly 30 may perform a cleaning process, an exposure process, an etching process, a development process, a deposition process and the like on the wafer. The aforementioned processes on the wafer may be performed in a semiconductor facility 400. The semiconductor facility 400 may be configured to perform a process in a semiconductor manufacturing line or a display manufacturing line.

In some embodiments, the manufacturing assembly 10, the supplying assembly 20, and the processing assembly 30 may include chemical liquid purification apparatuses 100, 200 and 300 for semiconductor manufacturing, respectively. The chemical liquid purification apparatuses 100, 200 and 300 for semiconductor manufacturing provided in the manufacturing assembly 10, the supplying assembly 20, and the processing assembly 30 may be substantially identical or similar to each other. The following description will focus on the chemical liquid purification apparatus 100 for semiconductor manufacturing provided in the manufacturing assembly 10, but the same description is also applicable to the chemical liquid purification apparatuses 200 and 300 for semiconductor manufacturing provided in the supplying assembly 20 and processing assembly 30. In FIG. 1, the chemical liquid purification apparatus 100 for semiconductor manufacturing includes first tank 110, first centrifuge 120, filter 130, and second tank 140, which are discussed further below.

FIG. 2 is a schematic diagram that schematically shows the chemical liquid purification apparatus for semiconductor manufacturing according to some embodiments.

Referring to FIG. 2, the chemical liquid purification apparatus 100 for semiconductor manufacturing may include a first line 160a, a first tank 110, a DC power supply 114, a second line 160b, a first centrifuge 120, a filter 130, and a second tank 140.

In the following description, a third direction Z may represent a direction in which the first tank 110 extends, and a first direction X and a second direction Y may represent directions parallel to a plane perpendicular to the third direction Z. In addition, the first direction X and the second direction Y may be directions perpendicular to each other, an upward direction may be understood as the third direction Z, and a downward direction may be understood as a direction opposite to the third direction Z.

The first line 160a may be configured to supply the chemical liquid 111 for semiconductor manufacturing to the first tank 110. For example, the first line 160a may provide a path through which the chemical liquid 111 for semiconductor manufacturing manufactured in the chemical liquid manufacturing facility for semiconductor manufacturing is supplied to the first tank 110. The first line 160a may be physically connected to the first tank 110. In some embodiments, the first line 160a may be connected to the top or bottom of the first tank 110.

The first tank 110 may be configured to store the chemical liquid 111 for semiconductor manufacturing. The first tank 110 is a tank that stores the chemical liquid 111 for semiconductor manufacturing to be purified, and may be configured to store a liquid or a gas. For example, if a high-pressure gas is stored in the first tank 110, the first tank 110 may be a ball tank. Alternatively, if a volatile liquid is stored in the first tank 110, the first tank 110 may be a tank with a floating loop. The first tank 110 may include a space therein that accommodates the first electrode 113, the second electrode 112, and the chemical liquid 111 for semiconductor manufacturing.

The first tank 110 may include an inlet port and an outlet port. The inlet port may be an inlet through which the chemical liquid 111 for semiconductor manufacturing flows into the first tank 110. The outlet port may be an outlet through which the chemical liquid 111 for semiconductor manufacturing is discharged to the outside of the first tank 110. The inlet port may be connected to the first line 160a, and the outlet port may be connected to the second line 160b.

In some embodiments, the outlet port may be configured to switch between an off-state in which the chemical liquid 111 for semiconductor manufacturing stored in the first tank 110 does not enter the second line 160b, and an on-state in which the chemical liquid 111 for semiconductor manufacturing stored in the first tank 110 enters the second line 160b. In some embodiments, the outlet port may be maintained in the off-state when the chemical liquid 111 for semiconductor manufacturing in the first tank 110 is processed. Also, the outlet port may be switched to the on-state when the processing on the chemical liquid 111 for semiconductor manufacturing is completed in the first tank 110.

In some embodiments, a first valve 170a and a first pump 180a may be disposed in the first line 160a. The first valve 170a may be configured to control the flow of the chemical liquid 111 for semiconductor manufacturing flowing through the first line 160a. For example, the first valve 170a may turn on and off the inflow of the chemical liquid 111 for semiconductor manufacturing flowing through the first line 160a. The first valve 170a may also adjust the flow rate of the chemical liquid 111 for semiconductor manufacturing flowing through the first line 160a. For example, when a critical amount or more of the chemical liquid 111 for semiconductor manufacturing is stored in the first tank 110, the first valve 170a may switched to the off-state. Accordingly, the chemical liquid 111 for semiconductor manufacturing may not be supplied into the first tank 110 containing a critical amount or more of the chemical liquid 111 for semiconductor manufacturing.

The first pump 180a may be configured to control the flow of the chemical liquid 111 for semiconductor manufacturing flowing through the first line 160a. For example, the first pump 180a may control the flow of the chemical liquid 111 for semiconductor manufacturing flowing through the first line 160a, by adjusting the internal pressure of the first line 160a. In addition, the first pump 180a may turn on and off the inflow of the chemical liquid 111 for semiconductor manufacturing flowing through the first line 160a, and may adjust the flow rate of the chemical liquid 111 for semiconductor manufacturing flowing through the first line 160a.

The first electrode 113, the second electrode 112, and the DC power supply 114 may be members provided to flocculate impurities contained in the chemical liquid 111 for semiconductor manufacturing in the first tank 110. The first electrode 113 and the second electrode 112 may be provided inside the first tank 110 to be spaced apart from each other. Either the first electrode 113 or the second electrode 112 may function as a cathode, and the other may act as an anode. At this time, the polarities of each of the first electrode 113 and the second electrode 112 may change depending on the progress of the process.

In some embodiments, each of the first electrode 113 and the second electrode 112 may extend parallel to each other in the third direction Z. Each of the first electrode 113 and the second electrode 112 may be connected to the DC power supply 114. The DC power supply 114 may be provided to supply a DC current to the first electrode 113 and the second electrode 112. However, in some embodiments, the DC power supply 114 may apply a mixture of DC current and AC current to each of the first electrode 113 and the second electrode 112. In some embodiments, the DC power supply 114 may apply a high voltage of 50 V or more to each of the first electrode 113 and the second electrode 112.

When the DC power supply 114 supplies the DC current to each of the first electrode 113 and the second electrode 112, a non-uniform electric field (dielectrophoresis) may be formed between the first electrode 113 and the second electrode 112. The non-uniform electric field may apply a dielectrophoretic force to a permanent dipole or an induced dipole of the impurities contained in the chemical liquid 111 for semiconductor manufacturing stored inside the first tank 110. Accordingly, the impurities are flocculated, and the size thereof may be amplified. The process in which the impurities contained in the chemical liquid 111 for semiconductor manufacturing stored inside the first tank 110 is flocculated will be described below referring to FIGS. 4 to 7.

The second line 160b may be configured to provide a path for the chemical liquid 111 for semiconductor manufacturing stored in the first tank 110 to move to the outside of the first tank 110. The second line 160b may supply the chemical liquid 111 for semiconductor manufacturing stored in the first tank 110 to the outside of the first tank 110. The second line 160b may be supplied with the chemical liquid 111 for semiconductor manufacturing that has been processed by the first electrode 113, the second electrode 112, and the DC power supply 114 in the first tank 110.

The second line 160b may be configured to connect the first tank 110 and the first centrifuge 120. In some embodiments, at least one of a second valve 170b and a second pump 180b may be disposed in the second line 160b. The second valve 170b may be configured to adjust the flow of the chemical liquid 111 for semiconductor manufacturing flowing through the second line 160b. For example, the second valve 170b may turn on and off the flow of the chemical liquid 111 for semiconductor manufacturing flowing through the second line 160b.

The second valve 170b may also adjust the flow rate of the chemical liquid 111 for semiconductor manufacturing flowing through the second line 160b. For example, the second valve 170b may maintain the off-state before the processing of the chemical liquid 111 for semiconductor manufacturing is completed in the first tank 110 by the first electrode 113, the second electrode 112, and the DC power supply 114. At this time, the chemical liquid 111 for semiconductor manufacturing moving along the second line 160b may not flow into the first centrifuge 120. Meanwhile, the second valve 170b may maintain the on-state when the processing of the chemical liquid 111 for semiconductor manufacturing is completed in the first tank 110 by the first electrode 113, the second electrode 112, and the DC power supply 114. At this time, the chemical liquid 111 for semiconductor manufacturing moving along the second line 160b may flow into the first centrifuge 120. Eventually, the second valve 170b may allow or block the flow of the chemical liquid 111 for semiconductor manufacturing into the first centrifuge 120.

The second pump 180b may be configured to control the flow of the chemical liquid 111 for semiconductor manufacturing flowing through the second line 160b. For example, the second pump 180b may control the flow of the chemical liquid 111 for semiconductor manufacturing by adjusting the pressure in the second line 160b. The second pump 180b may turn on and off the inflow of the chemical liquid 111 for semiconductor manufacturing flowing through the second line 160b. The second pump 180b may also adjust the flow rate of the chemical liquid 111 for semiconductor manufacturing flowing through the second line 160b.

The first centrifuge 120 may selectively separate impurities in the chemical liquid 111 for semiconductor manufacturing moving along the second line 160b. For example, the first centrifuge 120 may receive the chemical liquid 111 for semiconductor manufacturing processed in the first tank 110, separate particles contained in the chemical liquid 111 for semiconductor manufacturing by size through centrifugation, and may induce the particles into a form that can be purified.

The first centrifuge 120 may include a first region 122 and a second region 121 therein. The first region 122 may be disposed at a lower end inside the first centrifuge 120, and the second region 121 may be disposed at an upper end inside the first centrifuge. The first centrifuge 120 may separate particles such that particles having a small diameter among the particles contained in the chemical liquid 111 for semiconductor manufacturing are included in the first region 122, and particles having a large diameter among the particles contained in the chemical liquid 111 for semiconductor manufacturing are included in the second region 121. That is, the chemical liquid 111 for semiconductor manufacturing that flows into the first centrifuge 120 through the second line 160b is subjected to centrifugation, the chemical liquid 111 for semiconductor manufacturing containing impurities having large particles may be included in the second region 121, and the chemical liquid 111 for semiconductor manufacturing containing impurities having small particles may be included in the first region 122.

The third line 160c may be configured to connect the first centrifuge 120 and the second tank 140. The third line 160c is connected to the first region 122 of the first centrifuge 120, and the chemical liquid 111 for semiconductor manufacturing contained in the first region 122 may be supplied to the third line 160c. The chemical liquid 111 for semiconductor manufacturing supplied to the third line 160c may contain impurities having smaller particles than the impurities contained in the chemical liquid 111 for semiconductor manufacturing that are removed without being supplied to the third line 160c.

At least one of a third valve 170c and a third pump 180c may be disposed in the third line 160c, and the filter 130 is disposed. The third valve 170c may be configured to adjust the flow of the chemical liquid 111 for semiconductor manufacturing flowing through the third line 160c. For example, the third valve 170c may turn on and off the flow of the chemical liquid 111 for semiconductor manufacturing flowing through the third line 160c.

In addition, the third valve 170c may adjust the flow rate of the chemical liquid 111 for semiconductor manufacturing flowing through the third line 160c. For example, the third valve 170c may maintain the off-state before the centrifugation process on the chemical liquid 111 for semiconductor manufacturing is completed in the first centrifuge 120. At this time, the chemical liquid 111 for semiconductor manufacturing moving along the third line 160c may not flow into the second tank 140. Meanwhile, the third valve 170c may be switched to the on-state when the centrifugation process is completed in the first centrifuge 120. At this time, the chemical liquid 111 for semiconductor manufacturing moving along the third line 160c may flow into the second tank 140. Eventually, the third valve 170c may allow or block the flow of the chemical liquid 111 for semiconductor manufacturing into the second tank 140.

The third pump 180c may be configured to control the flow of the chemical liquid 111 for semiconductor manufacturing flowing through the third line 160c. For example, the third pump 180c may adjust the pressure in the third line 160c to control the flow of the chemical liquid 111 for semiconductor manufacturing. The third pump 180c may turn on and off the inflow of the chemical liquid 111 for semiconductor manufacturing flowing through the third line 160c. The third pump 180c may also adjust the flow rate of the chemical liquid 111 for semiconductor manufacturing flowing through the third line 160c.

The filter 130 may be configured to filter impurities in the chemical liquid 111 for semiconductor manufacturing flowing along the third line 160c. The filter 130 may include, for example, a Point of Use (POU) filter, a disposable filter, and a bulk cartridge filter. For example, the filter 130 may be replaced after filtering out impurities of a certain level or more.

For example, a membrane may be formed inside the filter 130. The membrane may include, for example, a filtration membrane. A plurality of pores may be formed in the membrane. The size of the pores in the membrane may be set to a degree that allows nanoparticle-sized impurities to be filtered. The membrane of the filter 130 may filter impurities in the chemical liquid 111 for semiconductor manufacturing flowing through the third line 160c. Accordingly, impurities may not be present in the chemical liquid 141 for semiconductor manufacturing provided to the second tank 140 via the filter 130.

For example, the filter 130 may include polypropylene (PP), polyethersulfone (PES), polyimide, high density polyethylene (HDPE), ultra-high molecular weight polyethylene (UPE), fluororesin (PTFE), polysulfone (PSF), nylon, or the like.

The second tank 140 may be connected to the third line 160c, and may be configured to store the chemical liquid 141 for semiconductor manufacturing. Impurities may not be present in the chemical liquid 141 for semiconductor manufacturing stored in the second tank 140.

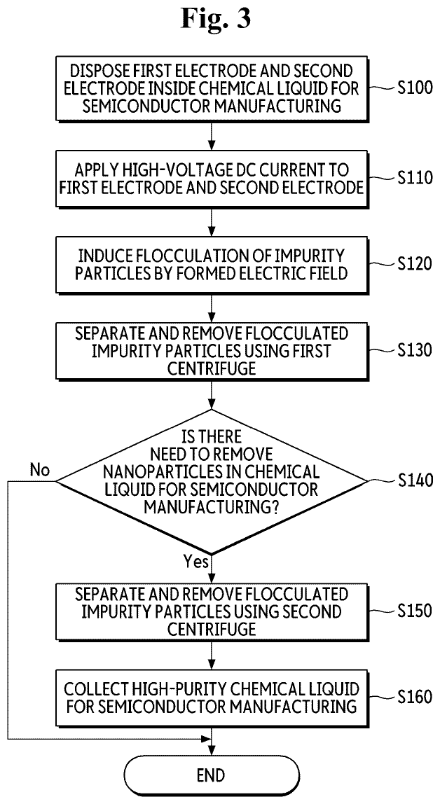

FIG. 3 is a flowchart for explaining a method for purifying a chemical liquid for semiconductor manufacturing according to some embodiments. FIGS. 4 to 7 are diagrams for explaining impurity flocculation in the chemical liquid for semiconductor manufacturing according to some embodiments. Hereinafter, a method for purifying the chemical liquid for semiconductor manufacturing according to some embodiments will be described referring to FIGS. 2 to 7.

First, the chemical liquid 111 for semiconductor manufacturing may be stored in the first tank 110 by controlling at least one of the first valve 170a and the first pump 180a. At this time, the second valve 170b may be in the off-state. When a critical amount or more of the chemical liquid 111 for semiconductor manufacturing is stored in the first tank 110, the first valve 170a may be switched to the off-state.

Referring to FIG. 4, impurities 40 may be contained in the chemical liquid 111 for semiconductor manufacturing stored in the first tank 110. The impurities 40 may be present in the chemical liquid 111 for semiconductor manufacturing in a dissolved state or in a particulate form. The impurities 40 may be materials containing silicon, such as silicate or silica (SiO₂). However, the materials contained in the impurities 40 are not limited to silicon. In some embodiments, the diameter of the impurities 40 contained in the chemical liquid 111 for semiconductor manufacturing may be in a range of 5 nm to 50 nm. However, the diameter of the impurities 40 is not limited to the above range and may be, for example, 100 nm or less.

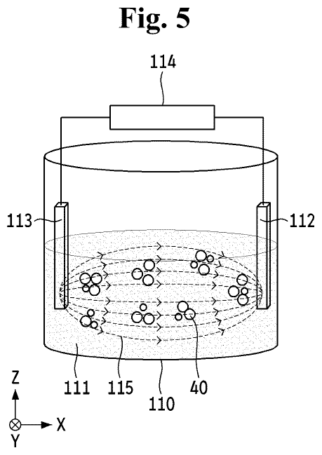

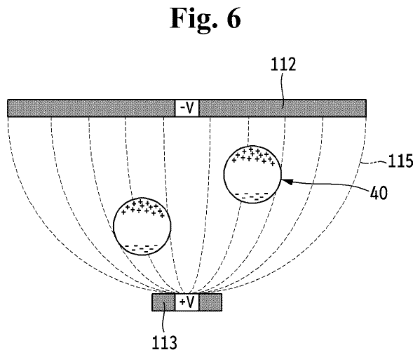

Referring to FIGS. 3 and 5, the first electrode 113 and the second electrode 112 may be disposed inside the chemical liquid 111 for semiconductor manufacturing (S100). As shown in FIG. 5, a part of the first electrode 113 and the second electrode 112 may be placed in the chemical liquid 111 for semiconductor manufacturing. After that, the DC power supply may be applied to each of the first electrode 113 and the second electrode 112, using the DC power supply 114 (S110). At this time, referring to FIG. 6 together, an electric field may be formed between the first electrode 113 and the second electrode 112. For example, if the first electrode 113 is a (+) electrode and the second electrode 112 is a (−) electrode, a line of electric force 115 may be induced from the first electrode 113 to the second electrode 112. Accordingly, an electric field of a non-uniform gradient may be generated between the first electrode 113 and the second electrode 112.

Flocculation of impurity 40 particles may be induced, using the electric field thus formed (S120). For example, when the line of electric force 115 is induced from the first electrode 113 to the second electrode 112, the line of electric force 115 may be induced in a form that diffuses from the first electrode 113 toward the second electrode 112. At this time, a stronger electric field may be formed in the vicinity of the electrode in which the gradient of the electric field is large, among the first electrode 113 and the second electrode 112. The impurities 40 may be flocculated by the gradient of the non-uniform electric field. For example, if the impurities 40 have no polarity, the impurities 40 may have the form of an electric dipole due to the electric dipole induction phenomenon caused by a non-uniform electric field. The magnitude and direction of the polarity induced to the impurities 40 may vary, depending on the frequency of the electric field, and dielectric properties, such as the conductivity and permittivity of each of the chemical liquid 111 for semiconductor manufacturing and the impurities 40.

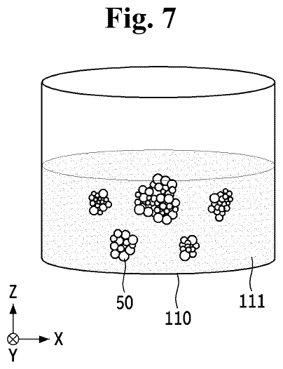

Referring to FIGS. 6 and 7, after the flocculation of the impurity 40 particles is induced using the electric field at step S120, the chemical liquid 111 for semiconductor manufacturing stored inside the first tank 110 may include an impurity dummy 50. The size of the impurity dummy 50 may be larger than the size of the impurities 40 of FIG. 4. In some embodiments, the diameter of the impurity dummy 50 may be in the range of 100 nm to 10 μm. However, the diameter of the impurity dummy 50 is not limited to the above range and may be, for example, 100 nm or more. The impurity dummy 50 may not stick to the surfaces of the first electrode 113 and the second electrode 112, and may still drift inside the chemical liquid 111 for semiconductor manufacturing.

Next, referring to FIGS. 2 and 3, the chemical liquid 111 for semiconductor manufacturing containing the impurity dummy 50 may flow into the first centrifuge 120 along the second line 160b, and the flocculated impurity dummy may be separated and removed using the first centrifuge 120 (S130). For example, the first centrifuge 120 centrifuges the chemical liquid 111 for semiconductor manufacturing flowing in along the second line 160b, and may separate the chemical liquid 111 for semiconductor manufacturing containing micro-sized impurity particles into the second region 121, and separate the chemical liquid 111 for semiconductor manufacturing containing nano-sized impurity particles into the first region 122. After that, the chemical liquid 111 for semiconductor manufacturing containing micro-sized impurity particles of the second region 121 may be removed.

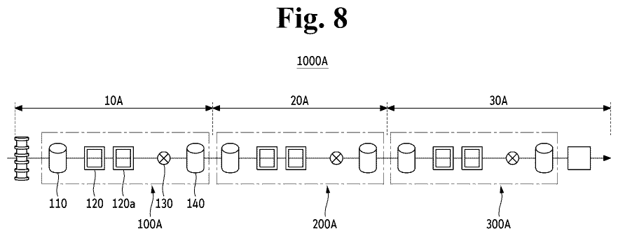

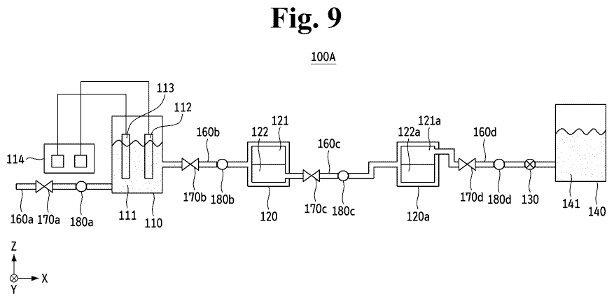

After that, if there is no need to remove the nano-sized impurity particles inside the chemical liquid 111 for semiconductor manufacturing of the first region 122 (S140—No), the process is ended, and the chemical liquid 111 for semiconductor manufacturing of the first region 122 may be supplied to the processing assembly 30. On the other hand, if there is a need to remove the nano-sized impurity particles inside the chemical liquid 111 of the first region 122 (S140—Yes), a secondary centrifugation may be performed, using a second centrifuge 120a to be described below referring to FIG. 8 (S150, S160). Hereinafter, the secondary centrifugation process will be described referring to FIGS. 8 and 9.

FIG. 8 is a schematic diagram that schematically shows a chemical liquid transferring system for semiconductor manufacturing according to some embodiments. FIG. 9 is a schematic diagram showing a chemical liquid purification apparatus for semiconductor manufacturing according to some embodiments. Hereinafter, repeated descriptions of the previous embodiments will not be provided, and the differences will be mainly described.

A chemical liquid transferring system 1000A for semiconductor manufacturing may include a manufacturing assembly 10A, a supplying assembly 20A, and a processing assembly 30A. Hereinafter, although the description will be mainly focused on the chemical liquid purification apparatus 100A for semiconductor manufacturing provided in the manufacturing assembly 10A, the same description is also applicable to the chemical liquid purification apparatuses 200A and 300A for semiconductor manufacturing provided in the supplying assembly 20A and the processing assembly 30A, respectively.

The chemical liquid purification apparatus 100A for semiconductor manufacturing may further include a second centrifuge 120a. The second centrifuge 120a may be disposed between the third line 160c and the second tank 140. The second centrifuge 120a may selectively separate impurities inside the chemical liquid 111 for semiconductor manufacturing moving along the third line 160c. For example, the second centrifuge 120a receives the chemical liquid 111 for semiconductor manufacturing stored in the first region 122 of the first centrifuge 120, and may separate particles contained in the chemical liquid 111 for semiconductor manufacturing by size through the centrifuge, and induce the particles in the form that can be purified.

The second centrifuge 120a may include a third region 121a and a fourth region 122a therein. The fourth region 122a may be disposed at a lower end inside the second centrifuge 120a, and the third region 121a may be disposed at an upper end inside the second centrifuge 120a. The second centrifuge 120a may separate the chemical liquid 111 for semiconductor manufacturing such that the high-purity chemical liquid 111 for semiconductor manufacturing, from which impurity particles are removed, is included in the third region 121a, and the chemical liquid 111 for semiconductor manufacturing including nano-sized impurity is included in the fourth region 122a. That is, the chemical liquid 111 for semiconductor manufacturing flowing into the second centrifuge 120a through the third line 160c may be centrifuged through the second centrifuge 120a, and as a result, the high-purity chemical liquid 111 for semiconductor manufacturing, from which impurities are removed, is included in the third region 121a, and the chemical liquid 111 for semiconductor manufacturing containing the nano-sized impurities may be included in the fourth region 122a.

The fourth line 160d may be configured to connect the second centrifuge 120a and the second tank 140. The fourth line 160d is connected to the third region 121a of the second centrifuge 120a, and the high-purity chemical liquid 111 for semiconductor manufacturing contained in the third region 121a may be supplied to the fourth line 160d.

At least one of a fourth valve 170d and a fourth pump 180d may be disposed in the fourth line 160d, and a filter 130 may be disposed therein. The fourth valve 170d may be configured to adjust the flow of the chemical liquid 111 for semiconductor manufacturing flowing through the fourth line 160d. For example, the fourth valve 170d may turn on and off the flow of the chemical liquid 111 for semiconductor manufacturing flowing through the fourth line 160d.

In addition, the fourth valve 170d may adjust the flow rate of the chemical liquid 111 for semiconductor manufacturing flowing through the fourth line 160d. For example, the fourth valve 170d may maintain the off-state before the centrifugation process on the chemical liquid 111 for semiconductor manufacturing is completed in the second centrifuge 120a. At this time, the chemical liquid 111 for semiconductor manufacturing moving along the fourth line 160d may not flow into the second tank 140. Meanwhile, the fourth valve 170d may maintain the on-state when the centrifugation process is completed in the second centrifuge 120a. At this time, the chemical liquid 111 for semiconductor manufacturing moving along the fourth line 160d may flow into the second tank 140. Eventually, the fourth valve 170d may allow or block the flow of the chemical liquid 111 for semiconductor manufacturing into the second tank 140.

The fourth pump 180d may be configured to control the flow of the chemical liquid 111 for semiconductor manufacturing flowing through the fourth line 160d. For example, the fourth pump 180d may adjust the pressure in the fourth line 160d to control the flow of the chemical liquid 111 for semiconductor manufacturing. The fourth pump 180d may turn on and off the inflow of the chemical liquid 111 for semiconductor manufacturing flowing through the fourth line 160d. The fourth pump 180d may adjust the flow rate of the chemical liquid 111 for semiconductor manufacturing flowing through the fourth line 160d.

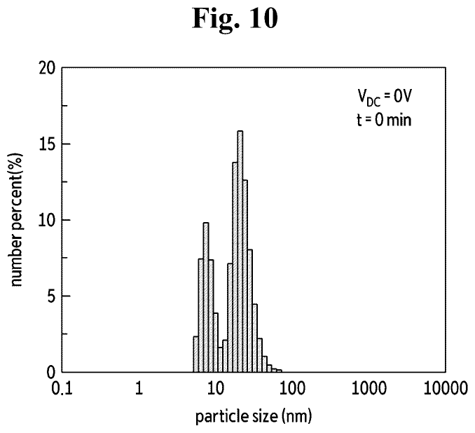

FIGS. 10 to 12 are graphs for explaining the flocculation of impurities in the chemical liquid 111 for semiconductor manufacturing according to some embodiments.

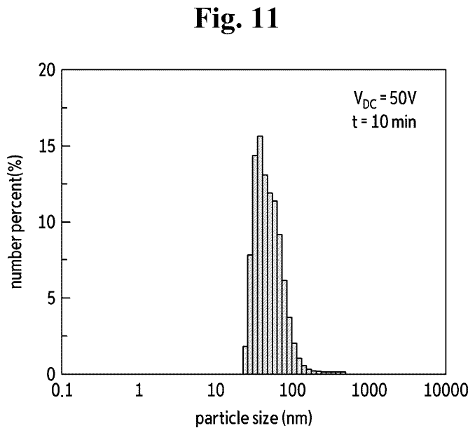

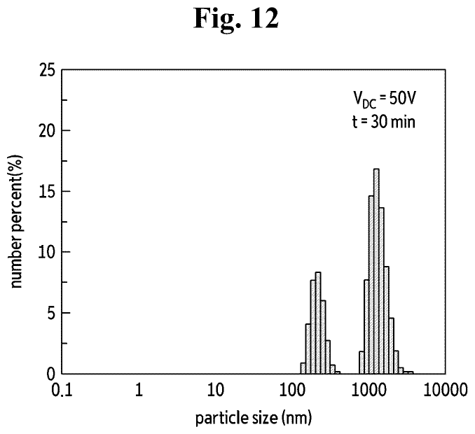

FIG. 10 is a graph that shows a particle size distribution of the impurities 40 inside the chemical liquid 111 for semiconductor manufacturing stored in the first tank 110 of FIG. 4 before the DC voltage is applied to the first electrode 113 and the second electrode 112. FIG. 11 is a graph that shows the particle size distribution of impurities 40 inside the chemical liquid 111 for semiconductor manufacturing stored in the first tank 110 of FIG. 5 when 10 minutes elapses after the DC voltage of 50 V is applied to the first electrode 113 and the second electrode 112 using the DC power supply 114. FIG. 12 is a graph that shows the particle size distribution of impurity dummy 50 in the chemical liquid 111 for semiconductor manufacturing stored in the first tank 110 of FIG. 7 when 30 minutes elapses after the DC voltage of 50 V is applied to the first electrode 113 and the second electrode 112 using the DC power supply 114.

Referring to FIG. 10, the diameter of the impurities 40 before applying the dielectrophoretic force using the non-uniform electric field to the permanent dipole or induced dipole of the impurities contained in the chemical liquid 111 for semiconductor manufacturing stored in the first tank 110 may be in the range of 5 nm to 50 nm. Referring to FIG. 12, when 30 minutes elapses after the high DC voltage of 50V is applied to the first electrode 113 and the second electrode 112, the impurities 40 may be flocculated to form an impurity dummy 50, and the diameter of the impurity dummy 50 may be in the range of 100 nm to 10μm.

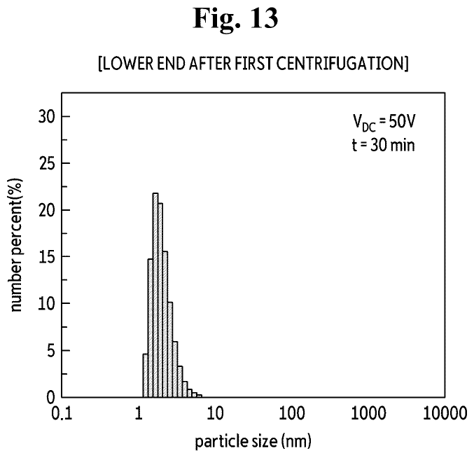

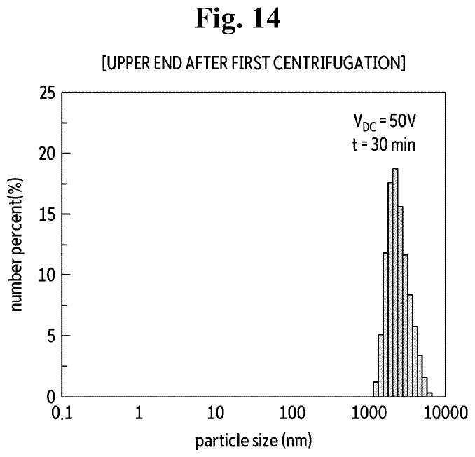

FIGS. 13 and 14 are graphs for explaining selective centrifugation of impurities inside the chemical liquid 111 for semiconductor manufacturing according to some embodiments.

FIGS. 13 and 14 are graphs showing the particle size distribution of impurities 40 contained in the chemical liquid 111 for semiconductor manufacturing contained in the first region 122 and the particle size distribution of impurities 40 contained in the chemical liquid 111 for semiconductor manufacturing contained in the second region 121, respectively, when the chemical liquid 111 for semiconductor manufacturing is centrifuged using the first centrifuge 120.

Referring to FIG. 13, when the chemical liquid 111 for semiconductor manufacturing flowing into the first centrifuge 120 through the second line 160b is centrifuged using the first centrifuge 120, the chemical liquid 111 for semiconductor manufacturing separated into the first region 122 may contain only impurity particles of 10 nm or less. Also, referring to FIG. 14, the chemical liquid 111 for semiconductor manufacturing separated into the second region 121 may contain only impurity particles of 1 μm or more. In this way, the chemical liquid 111 for semiconductor manufacturing in the second region 121 containing impurity particles of 1 μm or more may be removed.

In this way, in the chemical liquid purification apparatus 100 for semiconductor manufacturing according to some embodiments, impurities are flocculated by dielectrophoresis using the high-voltage DC power supply, the flocculated impurities are selectively separated by size using centrifugation, and finally, the chemical liquid 111 for semiconductor manufacturing is filtered using a filter, thereby obtaining a high-purity chemical liquid 111 for semiconductor manufacturing.

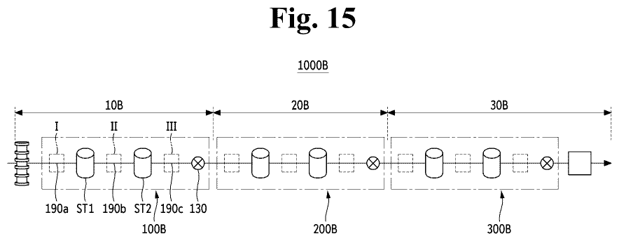

FIG. 15 is a schematic diagram that schematically shows a chemical liquid transferring system for semiconductor manufacturing according to some embodiments.

Referring to FIG. 15, a chemical liquid transferring system 1000B for semiconductor manufacturing may include a manufacturing assembly 10B, a supplying assembly 20B, and a processing assembly 30B. Hereinafter, although the description will be mainly focused on the chemical liquid purification apparatus 100B for semiconductor manufacturing provided in the manufacturing assembly 10B, the same description is also applicable to the chemical liquid purification apparatuses 200B and 300B for semiconductor manufacturing provided in the supplying assembly 20B and the processing assembly 30B, respectively. The manufacturing assembly 10B may include a first storage tank ST1, a second storage tank ST2, and a filter 130. The chemical liquid 111 for semiconductor manufacturing of a raw material state may be stored in the first storage tank ST1 via a first piping line 190a, and then stored in the second storage tank ST2 via a second piping line 190b. After that, the chemical liquid 111 for semiconductor manufacturing may be provided to the filter 130 via a third piping line 190c, and the chemical liquid 111 for semiconductor manufacturing filtered by the filter 130 may be provided to the supplying assembly 20B.

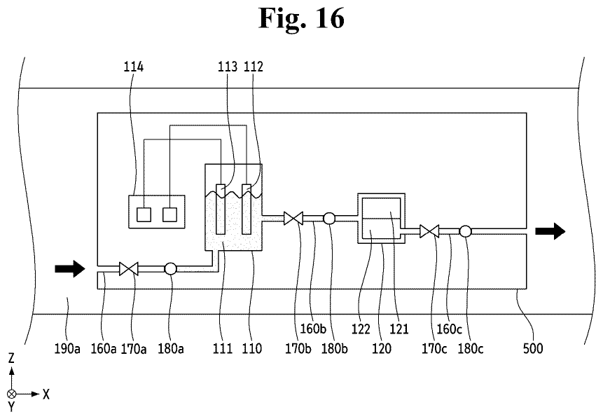

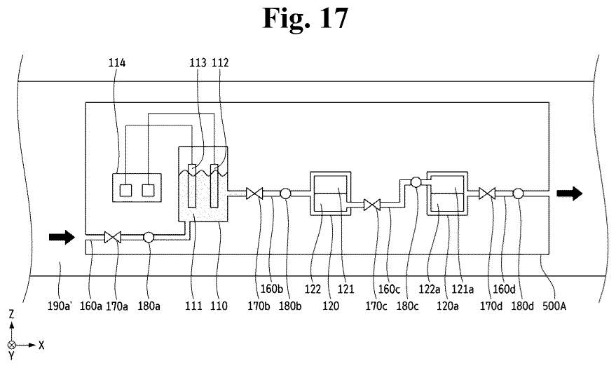

FIGS. 16 and 17 are schematic diagrams that schematically show a chemical liquid purification apparatus for semiconductor manufacturing inside the piping line of FIG. 15.

FIGS. 16 and 17 are enlarged views of a region I corresponding to the first piping line 190a of FIG. 15. The following description will focus on the region I corresponding to the first piping line 190a, but the same description is also applicable to the region II corresponding to the second piping line 190b and the region III corresponding to the third piping line 190c.

Referring to FIG. 16, the first piping line 190a may include a chemical liquid purification apparatus 500 for semiconductor manufacturing inside. The chemical liquid purification apparatus 500 for semiconductor manufacturing may include a structure similar to that of the chemical liquid purification apparatus 100 for semiconductor manufacturing described referring to FIG. 2.

Referring to FIG. 17, a first piping line 190a′ may include a chemical liquid purification apparatus 500A for semiconductor manufacturing inside. The chemical liquid purification apparatus 500A for semiconductor manufacturing may include a structure similar to that of the chemical liquid purification apparatus 100A for semiconductor manufacturing described referring to FIG. 9. That is, each of the chemical liquid purification apparatuses 100 and 100A for semiconductor manufacturing described referring to FIGS. 2 and 9, respectively, is also be applicable to the inside of the piping lines 190a, 190b and 190c that connect the storage tanks ST1 and ST2 which store the chemical liquid 111 for semiconductor manufacturing in the manufacturing assembly 10B of the chemical liquid transferring system 1000B for semiconductor manufacturing, and transfer the chemical liquid 111 for semiconductor manufacturing between the storage tanks ST1 and ST2.

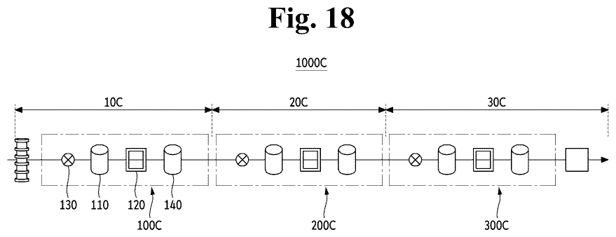

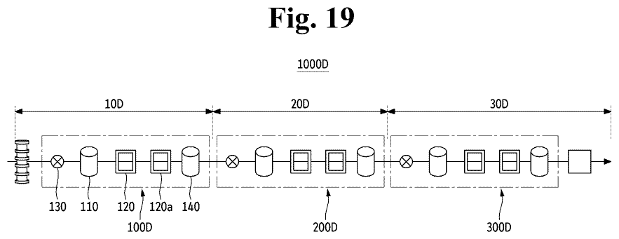

FIG. 18 is a schematic diagram showing a chemical liquid transferring system for semiconductor manufacturing according to some embodiments. FIG. 19 is a schematic diagram that schematically shows the chemical liquid transferring system for semiconductor manufacturing according to some embodiments.

First, referring to FIG. 18, a chemical liquid transferring system 1000C for semiconductor manufacturing may include a manufacturing assembly 10C including a chemical liquid purification apparatus 100C for semiconductor manufacturing, a supplying assembly 20C including a chemical liquid purification apparatus 200C for semiconductor manufacturing, and a processing assembly 30C including a chemical liquid purification apparatus 300C for semiconductor manufacturing. In the chemical liquid transferring system 1000C for semiconductor manufacturing of FIG. 17, unlike the chemical liquid transferring system 1000 for semiconductor manufacturing of FIG. 1, the filters 130 may be disposed at the front end of the first tank 110 in each of the manufacturing assembly 10C, the supplying assembly 20C and the processing assembly 30C. Next, referring to FIG. 19, a chemical liquid transferring system 1000D for semiconductor manufacturing may include a manufacturing assembly 10D including a chemical liquid purification apparatus 100D for semiconductor manufacturing, a supplying assembly 20D including a chemical liquid purification apparatus 200D for semiconductor manufacturing, and a processing assembly 30D including a chemical liquid purification apparatus 300D for semiconductor manufacturing. In the chemical liquid transferring system 1000D for semiconductor manufacturing of FIG. 19, unlike the chemical liquid transferring system 1000A for semiconductor manufacturing of FIG. 8, the filters 130 may be disposed at the front end of the first tank 110 in each of the manufacturing assembly 10D, the supplying assembly 20D, and the processing assembly 30D.

In this way, after some of the impurities contained in the chemical liquid 111 for semiconductor manufacturing are first filtered using the filter 130, the impurity particles are flocculated using the dielectrophoresis method, and the flocculated impurity particles may be selectively separated for size using centrifugation to recover the high-purity chemical liquid 111 for semiconductor manufacturing.

What is claimed is:

1. A chemical liquid purification apparatus for semiconductor manufacturing comprising:
a first tank configured to store a chemical liquid for semiconductor manufacturing containing impurities;
a first line configured to supply the chemical liquid for semiconductor manufacturing to the first tank;
a first electrode and a second electrode provided inside the first tank;
a DC power supply connected to each of the first electrode and the second electrode;
a second line configured to supply the chemical liquid for semiconductor manufacturing processed in the first tank to outside of the first tank; and
a first centrifuge which selectively separates the impurities inside the chemical liquid for semiconductor manufacturing moving along the second line.

2. The chemical liquid purification apparatus for semiconductor manufacturing of claim 1,
wherein the first centrifuge includes a first region and a second region that are separated from each other,
wherein the first centrifuge separates the chemical liquid for semiconductor manufacturing into chemical liquid for semiconductor manufacturing separated into the first region and chemical liquid for semiconductor manufacturing separated into the second region, and
the chemical liquid purification apparatus for semiconductor manufacturing further comprises a third line configured to supply the chemical liquid for semiconductor manufacturing separated into the first region to outside of the first centrifuge.

3. The chemical liquid purification apparatus for semiconductor manufacturing of claim 2, further comprising:
a filter configured to filter the impurities in the chemical liquid for semiconductor manufacturing moving along the third line.

4. The chemical liquid purification apparatus for semiconductor manufacturing of claim 2, further comprising:
a second centrifuge which selectively separates the impurities in the chemical liquid for semiconductor manufacturing moving along the third line, and includes a third region and a fourth region that are separated from each other,
wherein the second centrifuge separates the chemical liquid for semiconductor manufacturing into chemical liquid for semiconductor manufacturing separated into the third region and chemical liquid for semiconductor manufacturing separated into the fourth region,
wherein the chemical liquid purification apparatus for semiconductor manufacturing further comprises a fourth line configured to supply the chemical liquid for semiconductor manufacturing separated into the third region to outside of the second centrifuge,
wherein the fourth region is disposed below the third region inside the second centrifuge.

5. The chemical liquid purification apparatus for semiconductor manufacturing of claim 4, further comprising:
a filter configured to filter the impurities in the chemical liquid for semiconductor manufacturing moving along the fourth line.

6. The chemical liquid purification apparatus for semiconductor manufacturing of claim 1,
wherein a diameter of the impurities in the chemical liquid for semiconductor manufacturing moving along the second line is greater than a diameter of the impurities in the chemical liquid for semiconductor manufacturing supplied to the first tank along the first line.

7. The chemical liquid purification apparatus for semiconductor manufacturing of claim 1,
wherein the DC power supply applies a voltage of 50 V or more to each of the first electrode and the second electrode.

8. The chemical liquid purification apparatus for semiconductor manufacturing of claim 1,
wherein the impurities are dissolved in the chemical liquid for semiconductor manufacturing.

9. A chemical liquid purification apparatus for semiconductor manufacturing comprising:
a first tank configured to store a chemical liquid for semiconductor manufacturing containing impurities;
a first line configured to supply the chemical liquid for semiconductor manufacturing to the first tank;
a first electrode and a second electrode provided inside the first tank;
a DC power supply configured to supply a DC current to each of the first electrode and the second electrode;
a second line configured to supply the chemical liquid for semiconductor manufacturing processed in the first tank to outside of the first tank;
a centrifuge which selectively separates impurities in the chemical liquid for semiconductor manufacturing moving along the second line and stores the impurities in a first region and a second region separated from each other, wherein the centrifuge separates the chemical liquid for semiconductor manufacturing into chemical liquid for semiconductor manufacturing separated into the first region and chemical liquid for semiconductor manufacturing separated into the second region;
a third line configured to supply the chemical liquid for semiconductor manufacturing separated into the first region to outside of the centrifuge;
a filter configured to filter impurities in the chemical liquid for semiconductor manufacturing moving along the third line; and
a second tank connected to the filter through the third line,
wherein a particle size of the impurities in the chemical liquid for semiconductor manufacturing separated into the first region is smaller than a particle size of the impurities in the chemical liquid for semiconductor manufacturing separated into the second region.

10. The chemical liquid purification apparatus for semiconductor manufacturing of claim 9,
wherein a diameter of the impurities in the chemical liquid for semiconductor manufacturing supplied into the first tank along the first line is smaller than a diameter of the impurities in the chemical liquid for semiconductor manufacturing moving along the second line.

11. The chemical liquid purification apparatus for semiconductor manufacturing of claim 10,
wherein the diameter of the impurities in the chemical liquid for semiconductor manufacturing supplied into the first tank along the first line is in the range of 5 nm to 50 nm, and
the diameter of the impurities in the chemical liquid for semiconductor manufacturing moving along the second line is in the range of 100 nm to 10 μm.

12. The chemical liquid purification apparatus for semiconductor manufacturing of claim 10,
wherein the diameter of the impurities in the chemical liquid for semiconductor manufacturing supplied to the first tank along the first line is 100 nm or less, and the diameter of the impurities in the chemical liquid for semiconductor manufacturing moving along the second line is 100 nm or more.

13. The chemical liquid purification apparatus for semiconductor manufacturing of claim 9,
wherein the impurities include silicon.

14. The chemical liquid purification apparatus for semiconductor manufacturing of claim 9, further comprising:
at least one of a first valve and a first pump which are disposed on the first line and are configured to adjust a flow rate of the chemical liquid for semiconductor manufacturing moving along the first line; and
at least one of a second valve and a second pump which are disposed on the second line and are configured to adjust the flow rate of the chemical liquid for semiconductor manufacturing moving along the second line.

15. A chemical liquid transferring system for semiconductor manufacturing, comprising:
a manufacturing assembly configured to manufacture a chemical liquid for semiconductor manufacturing containing impurities;
a supplying assembly configured to supply the chemical liquid for semiconductor manufacturing manufactured in the manufacturing assembly to an outside; and
a processing assembly configured to receive the chemical liquid for semiconductor manufacturing from the supplying assembly and process a wafer, using the chemical liquid for semiconductor manufacturing received from the supplying assembly,
wherein at least one of the manufacturing assembly, the supplying assembly, and the processing assembly includes a chemical liquid purification apparatus for semiconductor manufacturing,
wherein the chemical liquid purification apparatus for semiconductor manufacturing includes:
a first tank configured to store the chemical liquid for semiconductor manufacturing;
a first line configured to supply the chemical liquid for semiconductor manufacturing to the first tank;
a first electrode and a second electrode provided inside the first tank;
a DC power supply configured to supply a DC current to each of the first electrode and the second electrode;
a second line configured to supply the chemical liquid for semiconductor manufacturing processed in the first tank to outside of the first tank; and
a first centrifuge which selectively separates impurities in the chemical liquid for semiconductor manufacturing moving along the second line.

16. The chemical liquid transferring system for semiconductor manufacturing of claim 15,
wherein the first centrifuge includes a first region and a second region separated from each other, and
the first centrifuge centrifuges the chemical liquid for semiconductor manufacturing moving along the second line to separate the chemical liquid for semiconductor manufacturing into chemical liquid for semiconductor manufacturing containing micro-sized impurities and chemical liquid for semiconductor manufacturing containing nano-sized impurities, wherein the chemical liquid for semiconductor manufacturing containing micro-sized impurities is separated into the first region, and the chemical liquid for semiconductor manufacturing containing nano-sized impurities is separated into the second region.

17. The chemical liquid transferring system for semiconductor manufacturing of claim 15,
wherein the first centrifuge separates the impurities in the chemical liquid for semiconductor manufacturing moving along the second line by particle size,
the first centrifuge includes a first region and a second region that are different from each other, wherein the first centrifuge separates the chemical liquid for semiconductor manufacturing into chemical liquid for semiconductor manufacturing separated into the first region and chemical liquid for semiconductor manufacturing separated into the second region, and
a particle size of the impurities in the chemical liquid for semiconductor manufacturing separated into the first region is smaller than a particle size of the impurities in the chemical liquid for semiconductor manufacturing separated into the second region.

18. The chemical liquid transferring system for semiconductor manufacturing of claim 17, further comprising:
a third line which is connected to the first region and configured to supply the chemical liquid for semiconductor manufacturing separated into the first region to outside of the first centrifuge; and
a second centrifuge which selectively separates the impurities in the chemical liquid for semiconductor manufacturing moving along the third line.

19. The chemical liquid transferring system for semiconductor manufacturing of claim 18, further comprising:
at least one of a third valve and a third pump which are disposed on the third line and configured to adjust a flow rate of the chemical liquid for semiconductor manufacturing moving along the third line.

20. The chemical liquid transferring system for semiconductor manufacturing of claim 15,
wherein a diameter of the impurities in the chemical liquid for semiconductor manufacturing supplied into the first tank along the first line is smaller than a diameter of the impurities in the chemical liquid for semiconductor manufacturing moving along the second line.
